(19) United States
(12) Patent Application Publication
(10) Pub. No.: US 2022/0190271 A1
(43) Pub. Date: Jun. 16, 2022

(54) Display Substrate and Manufacturing Method Thereof, and Display Apparatus

(71) Applicant: BOE Technology Group Co., Ltd., Beijing (CN)

(72) Inventors: Xiang LI, Beijing (CN); Shi SHU, Beijing (CN); Yong YU, Beijing (CN); Chuanxiang XU, Beijing (CN); Wei HE, Beijing (CN); Yang YUE, Beijing (CN); Haitao HUANG, Beijing (CN); Wei LI, Beijing (CN); Qi YAO, Beijing (CN)

(21) Appl. No.: 17/485,522

(22) Filed: Sep. 27, 2021

(30) Foreign Application Priority Data
Dec. 16, 2020 (CN) 202011488120.2

(51) Int. Cl. H01L 51/50; H01L 51/52; H01L 51/56; H01L 27/32

(52) U.S. Cl. CPC H01L 51/502; H01L 27/3246; H01L 51/56; H01L 51/5218

(57) ABSTRACT

A display substrate, a manufacturing method thereof, and a display apparatus are provided. The display substrate includes a base substrate, a light-emitting structure layer disposed on the base substrate and a color conversion layer disposed on a light exiting side of the light-emitting structure layer. The light-emitting structure layer includes a first electrode, a second electrode and a light-emitting layer disposed between the first electrode and the second electrode, wherein the first electrode at least includes a first part and a second part which are connected to each other, and a first interior angle is formed between the first part and the second part, and the first interior angle is greater than 0 and less than 180 degrees.

### CROSS-REFERENCE TO RELATED APPLICATION

The present application claims priority of Chinese Patent Application No. 202011488120.2 filed to the CNIPA on Dec. 16, 2020, the content of which is hereby incorporated by reference.

### TECHNICAL FIELD

The present disclosure relates to, but is not limited to, the field of display technology, and particularly relates to a display substrate, a method for manufacturing the display substrate, and a display apparatus.

### BACKGROUND

With continuous developments of display technology, quantum dot display technology has attracted more and more attention because of its unique emitting properties, good stability, wide color gamut and low cost. At present, display panels using the quantum dot display technology generally excite quantum dot materials to emit red light and green light by blue light emitted from light emitting devices in an array substrate, thus realizing colorful display.

At present, high-end large-size display products mainly use white organic light emitting diode+color filter (WOLED+CF) and quantum dot back light TV, while display technologies under development include quantum dot-organic light emitting diode (QD-OLED), ink-jet printing (UP) OLED, quantum dot color filter-liquid crystal display (QDCF-LCD), ink-jet printing electroluminescence (IJP QDEL) and micro-light-emitting secondary light (Micro LED) etc. As for the self-luminous large-size display technology, the QD-OLED has great potential to challenge WOLED+CF in 3 to 5 years, thus creating a brand-new market situation.

Among them, the QD-OLED has potential technical advantages, such as high resolution, high color gamut and high color purity, and has no dependence on viewing angles. In addition, the QD-OLED has potential to be applied in large-scale products or high color gamut products, and may be compatible with medium-sized ultra-high definition (UHD) and high-value products.

### SUMMARY

The following is a summary of the subject matters detailed herein. This summary is not intended to limit the protection scope of the claims.

In a first aspect, an embodiment of the present disclosure provides a display substrate, which includes a base substrate, a light-emitting structure layer disposed on the base substrate and a color conversion layer disposed on a light exiting side of the light-emitting structure layer. The light-emitting structure layer includes a first electrode, a second electrode and a light-emitting layer disposed between the first electrode and the second electrode, wherein the first electrode at least includes a first part and a second part which are connected to each other, and a first interior angle is formed between the first part and the second part, and the first interior angle is greater than 0 and less than 180 degrees.

In an exemplary embodiment, the first interior angle is greater than or equal to 90 degrees and less than 180 degrees.

In an exemplary embodiment, the first interior angle is greater than or equal to 110 degrees and less than 180 degrees.

In an exemplary embodiment, the light-emitting layer includes a first groove portion recessed towards the base substrate, and the first groove portion is disposed on the first electrode.

In an exemplary embodiment, the second electrode includes a second groove portion recessed towards the base substrate, and the second groove portion is disposed on the first groove portion.

In an exemplary embodiment, the light-emitting structure layer further includes a first planarization layer disposed on the base substrate and a second planarization layer disposed on the first planarization layer, wherein an opening is formed in the second planarization layer, and a second slope angle is formed between a side wall of the opening and the first planarization layer; the second slope angle is greater than 0 and less than or equal to 90 degrees; the first part is disposed on a bottom wall of the opening and the second part is disposed on the side wall of the opening.

In an exemplary embodiment, the light-emitting structure layer further includes a pixel definition layer disposed on the second planarization layer, wherein the pixel definition layer is provided with a pixel opening, and the pixel opening exposes the first part and the second part.

In an exemplary embodiment, the first electrode further includes a third part connected to the second portion, and the third part is located between the second planarization layer and the pixel definition layer.

In an exemplary embodiment, an area of the third part is 5%-15% of an area of the pixel opening.

In an exemplary embodiment, the second part is disposed on a sidewall of an opening of the second planarization layer and a sidewall of the pixel opening.

In an exemplary embodiment, the second planarization layer and/or the pixel definition layer are made of a light reflective material.

In an exemplary embodiment, a material of the pixel definition layer is a resin material doped with inorganic particles.

In an exemplary embodiment, the first electrode includes a light reflective material.

In an exemplary embodiment, the first electrode includes a first conductive layer, a second conductive layer which are stacked, and a reflective layer disposed between the first conductive layer and the second conductive layer.

In an exemplary embodiment, the first interior angle ranges from 105 degrees to 135 degrees.

In an exemplary embodiment, the light-emitting structure layer further includes at least one of a hole injection layer and a hole transport layer which are sequentially stacked between the first electrode and the light-emitting layer; and/or the light-emitting structure layer further includes at least one of a charge generation layer, an electron transport layer and an electron injection layer which are sequentially stacked and disposed between the light-emitting layer and the second electrode, and at least one of the hole injection layer, the hole transport layer, the charge generation layer, the electron transport layer and the electron injection layer includes a third groove portion which is recessed towards a direction of the base substrate.

In a second aspect, an embodiment of the present disclosure further provides a display apparatus including any of the foregoing display substrate.

In a third aspect, an embodiment of the present disclosure provides a method for manufacturing a display substrate, including:

forming a light-emitting structure layer on a base substrate; the light-emitting structure layer includes a first electrode, a second electrode and a light-emitting layer disposed between the first electrode and the second electrode, wherein the first electrode at least includes a first part and a second part which are connected to each other, and a first interior angle is formed between the first part and the second part, and the first interior angle is greater than 0 and less than 180 degrees; and

forming a color conversion layer on a light emitting side of the light-emitting structure layer.

Of course, the implementation of any product or method of the present disclosure does not necessarily need to realize all the advantages mentioned above at the same time. Other features and advantages of the present disclosure will be set forth in the following embodiments of the description, and in part will become apparent from the embodiments of the description, or be learned by practice of the present disclosure. The purpose and other advantages of the embodiments of the present disclosure may be realized and obtained through the structure specifically pointed out in the description, the claims and the drawings.

Other aspects will become apparent upon reading and understanding accompanying drawings and the detailed description.

### BRIEF DESCRIPTION OF DRAWINGS

The drawings are used to provide a further understanding of technical solutions of the present disclosure and constitute a part of the description, which are used together with the embodiments of the present disclosure to explain the technical solutions of the present disclosure and do not constitute limitations on the technical solutions of the present disclosure. The shape and size of each component in the drawings do not reflect true scales and only to be used to schematically illustrate contents of the present disclosure.

FIG. 1 is a curve graph showing a propagation angle of light emitted from a light-emitting layer and an intensity of light emitted from the light-emitting layer.

FIG. 2 is a sectional view of a display substrate.

FIG. 3 is a sectional view of a display substrate according to an embodiment of the present disclosure.

FIG. 4 is a first sectional view of a light-emitting structure layer in a display substrate according to an embodiment of the present disclosure;

FIG. 5 is a curve graph showing a relation between a first interior angle a and a reduction of a cross-color percentage of adjacent sub-pixels.

FIG. 6 is a curve graph of the first interior angle a and the light emitting efficiency increased by the light-emitting structure layer according to an embodiment of the present disclosure.

FIG. 7 is a second sectional view of a light-emitting structure layer in a display substrate according to an embodiment of the present disclosure.

FIG. 8 is a sectional view of a display apparatus according to an embodiment of the present disclosure.

### DETAILED DESCRIPTION

Specific implementations of the present disclosure will be described further in detail below with reference to the accompanying drawings and embodiments. The following embodiments are used to describe the present disclosure, but are not used to limit the scope of the present disclosure. The embodiments and features in the embodiments in the present disclosure may be combined randomly if there is no conflict.

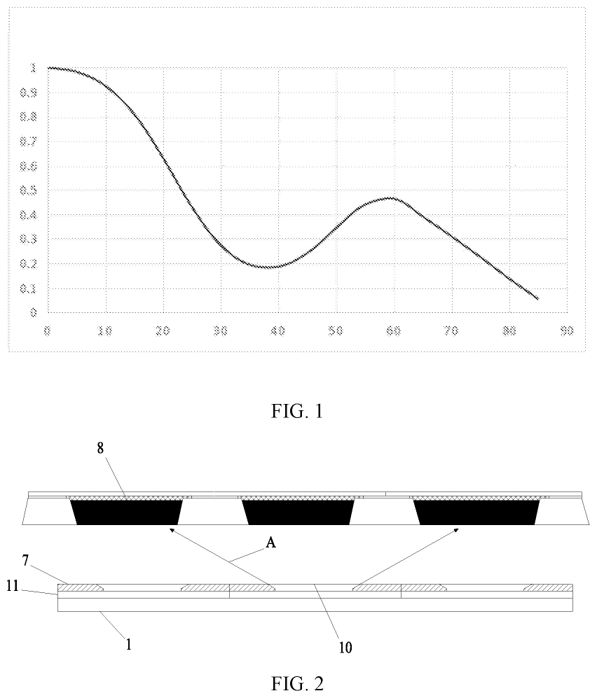

In a QD-OLED display structure, there are problems such as low light-emitting brightness of light-emitting materials, serious cross-color problems between sub-pixels, etc. Herein, reasons for color cross between sub-pixels are as follows: 1. a gap between a light-emitting layer and a color conversion layer is too large, causing light emitted by the light-emitting layer to enter the adjacent sub-pixels. 2. FIG. 1 is a curve graph showing a propagation angle of light emitted from the light-emitting layer and intensity of light emitted from the light-emitting layer. In FIG. 1, an abscissa is a propagation angle of light emitted from the light-emitting layer, and an ordinate is an intensity of light emitted from the light-emitting layer. As shown in FIG. 1, the intensity of light emitted by the light-emitting layer decreases with an increase of the propagation angle of light. When the propagation angle of light emitted from the light-emitting layer is 40 degrees-60 degrees, the light intensity will increase. In this case, light with a large angle will propagate to adjacent sub-pixels, which will excite color conversion layers of the adjacent sub-pixels to emit light, affecting a normal display and causing the problem of cross-color.

The above problems may be solved by adopting the following solution: 1. reduce a distance between the light-emitting layer and the color conversion layer. Solutions such as two encapsulation layers which are stacked and a film layer which is thinned may be adopted to reduce the distance between the light-emitting layer and the color conversion layer. 2. Change the propagation angle of the light emitted by the light-emitting layer, and change light with a large angle into light with a small angle. A lens solution and a high-refractive material solution may be adopted to change the propagation angle of the light emitted by the light-emitting layer. Among them, there is a risk of reliability in the solution with two encapsulation layers which are stacked. There is a light emission problem caused by uneven coating with the solution of thinning film layers. And the lens solution and the high refractive material solution increase the process difficulty and costs.

FIG. 2 is a sectional view of a display substrate. As shown in FIG. 2, the display substrate includes a base substrate 1 and multiple sub-pixels 10 disposed on the base substrate 1, wherein each sub-pixel 10 includes a drive structure layer 11 disposed on the base substrate 1, a light-emitting structure layer 7 disposed on the drive structure layer 11 and a color conversion layer 8 disposed on a light exiting side of the light-emitting structure layer 7. The light-emitting structure layer includes a first electrode, a second electrode, and a light-emitting layer disposed between the first electrode and the second electrode. There is a gap between the color conversion layer 8 and the light-emitting structure layer 7. When the light-emitting structure layer 7 emits light, light with a large angle A emitted by the light-emitting structure layer 7 will enter adjacent sub-pixels 10 through the gap between the color conversion layer 8 and the light-emitting structure layer 7, resulting in a cross-color problem of adjacent sub-pixels.

A viewing angle of QD-OLED depends on a distribution of viewing angle of a color conversion layer, and has nothing to do with a viewing angle of the light-emitting structure layer. Therefore, in a manufacturing process of the display substrate, it is not necessary to consider the viewing angle of the light-emitting structure layer, but only need to consider increasing a light-emitting area of the light-emitting structure layer, increasing a light-emitting efficiency of the light-emitting structure layer and increasing a light field distribution of the light-emitting structure layer.

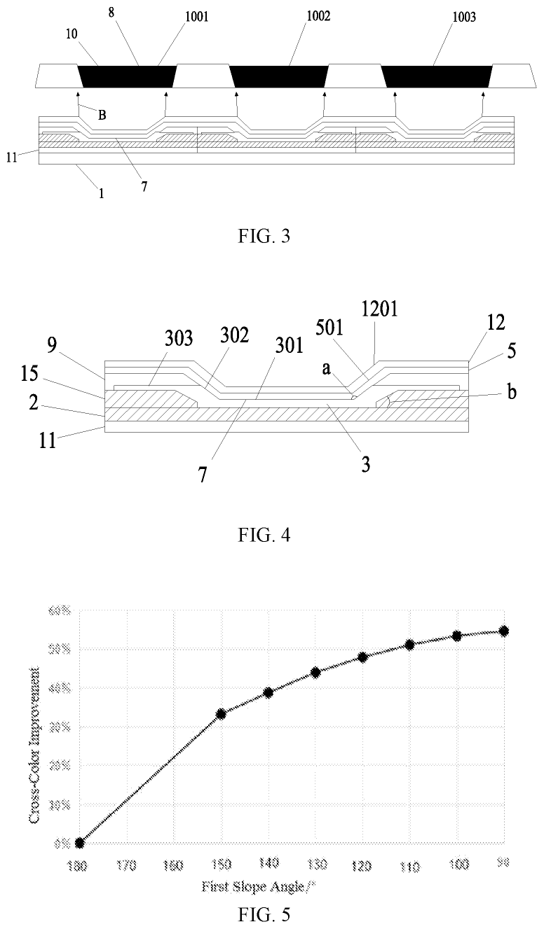

FIG. 3 is a sectional view of a display substrate according to an embodiment of the present disclosure. As shown in FIG. 3, the display substrate of the embodiment of the present disclosure includes a base substrate 1 and multiple sub-pixels 10 disposed on the base substrate 1, wherein the multiple sub-pixels 10 may emit light of different colors. Each sub-pixel 10 includes a drive structure layer 11 disposed on the base substrate 1, a light-emitting structure layer 7 disposed on the drive structure layer 11, and a color conversion layer 8 disposed on a light exiting side of the light-emitting structure layer 7. The color conversion layer 8 is configured to convert light of a first wavelength emitted by the light-emitting structure layer 7 into light of a second wavelength, that is, the color conversion layer 8 may convert the light emitted by the light-emitting structure layer 7 into light of other colors. For example, the light of the first wavelength may be blue light, and light of the second wavelength may be green light or red light. All the blue light emitted by the light-emitting structure layer 7 after being converted by the color conversion layer may be light of the second wavelength, or partially be the light of the second wavelength. The drive structure layer 11 is connected to a first electrode in the light-emitting structure layer 7, and is configured to drive the light-emitting structure layer 7 to emit light. The drive structure layer 11 mainly includes a pixel drive circuit composed of multiple Thin Film Transistors (TFT). For example, the drive structure layer 11 may have a structure of 2T1C (two thin film transistors and one capacitor), 5T1C (five thin film transistors and one capacitor), 7T1C (seven thin film transistors and one capacitor), etc., which are not limited hereto. Exemplarily, the drive structure layer 11 may include two thin film transistors TFTs, namely TFT1 and TFT2, wherein each thin film transistor TFT may include a gate G, a source S, a drain D, and an active layer connecting the source S and the drain D. Illustratively, the transistors TFT1 and TFT2 may have a double-gate structure. Herein, a drain D of the TFT1 is electrically connected to the first electrode 3 of the light-emitting structure layer.

In an exemplary embodiment, the color conversion layer may be a fluorescent material or a quantum dot material, which may be determined according to actual use requirements, which is not limited hereto in the embodiment of the present disclosure.

FIG. 4 is a first sectional view of a light-emitting structure layer in a display substrate according to an embodiment of the present disclosure. As shown in FIG. 3 and FIG. 4, the light-emitting structure layer 7 includes a first electrode 3 disposed on the drive structure layer 11, wherein the first electrode 3 at least includes a first part 301 and second parts 302 which are connected to each other, wherein a first interior angle a is formed between the first part 301 and a second part 302, and the first interior angle a is greater than 0 degree and less than 180 degrees.

In an exemplary embodiment, the first part and the second parts may be flat or be formed regularly or irregularly by, i.e., curved surfaces, which is not to be repeated in detail here in the embodiments of the present disclosure.

According to the embodiment of the present disclosure, the first electrode 3 is divided into the first part 301 and the second parts 302, so that the first interior angle a is formed between the first part 301 and the second parts 302, thereby changing a light field distribution of the light-emitting layer, thus the large angle of light emitted by the light-emitting layer is changed into a small angle, light-emitting intensity of the light with large angle emitted by the light-emitting layer is reduced, cross-color between adjacent sub-pixels is reduced and the color gamut of the display apparatus is improved. Among them, the light with a large angle refers to light emitted by the light-emitting layer that may enter adjacent sub-pixels through a gap between the color conversion layer 8 and the light-emitting structure layer 7. The light with a small angle refers to light emitted by the light-emitting layer that can directly enter the corresponding color conversion layer 8.

In an exemplary embodiment, the light-emitting layer 5 includes a first groove portion 501 recessed towards the base substrate, wherein the first groove portion is disposed on the first electrode 3. In the embodiment of the present disclosure, the light-emitting layer 5 is deposited on the first electrode 3, and the first groove portion 501 is formed on the light-emitting layer 5 by the first electrode 3, thereby changing a light field distribution of the light-emitting layer 5 and reducing the cross-color between adjacent sub-pixels.

In an exemplary embodiment, the second electrode 12 includes a second groove portion 1201 recessed towards the base substrate, and the second groove portion 1201 is disposed on the first groove portion 501.

As shown in FIG. 3, a red sub-pixel (R) 1001, a green sub-pixel (G) 1002 and a blue sub-pixel (B) 1003 are arranged in array on the base substrate 1. The green sub-pixel (G) 1002 is located between the red sub-pixel (R) 1001 and the blue sub-pixel (B) 1003. When the green sub-pixel (G) 1002 emits light, the first electrode 3 in the green sub-pixel (G) 1002 changes a light field distribution of the light-emitting layer 5, so that light with large angle emitted by the green sub-pixel (G) 1002 is changed into light with small angle, thereby reducing the light-emitting intensity of the light with large angle emitted by the green sub-pixel (G) 1002, and reducing the cross-color of the red sub-pixel (R) 1001 and blue sub-pixel (B) 1003 of the light with large angle emitted by the green sub-pixel (G) 1002.

FIG. 5 is a curve graph showing a relation between a first interior angle a and a reduction of a cross-color percentage of adjacent sub-pixels. In FIG. 5, an abscissa is an angle of the first interior angle a. In FIG. 5, an ordinate is a percentage of a reduction of cross-color of adjacent sub-pixels. The first interior angle a can control the appearance of the light-emitting layer 5, changing a light field distribution of the light-emitting layer 5, and reducing the cross-color of adjacent sub-pixels. As shown in FIG. 5, the smaller the first interior angle a is, the smaller the crosstalk between adjacent sub-pixels. Taking the crosstalk by illuminated sub-pixel R to adjacent sub-pixel G and sub-pixel B as an example, when a variation value of the first interior angle a is 150 degrees to 90 degrees, a range of reduction of the crosstalk to the adjacent sub-pixel G and sub-pixel B is 30%-55%. However, with a decrease of the first interior angle a, an opening formed between the second parts will gradually become smaller, which will make it more difficult to manufacture other film layers deposited on the first electrode, and easily cause other film layers to break between the second parts. For example, when the first interior angle a is less than 90 degrees, when the second electrode is deposited on the first electrode, it is easy to cause the second electrode to break, which affects the display effect. When the first interior angle a is 120 degrees, the second electrode may be deposited on the first electrode normally. When the first interior angle a is less than 110 degrees and the second electrode is deposited on the first electrode, it is easy to cause the second electrode to break, which affects the display effect. The first electrode may be an anode and the second electrode may be a cathode.

In an exemplary embodiment, the first interior angle a is greater than or equal to 90 degrees and less than 180 degrees, thereby reducing cross-color of adjacent sub-pixels and preventing the film layers disposed on the first electrode from breaking.

In an exemplary embodiment, the first interior angle a in the embodiment of the present disclosure is greater than or equal to 110 degrees and less than 180 degrees, so as to reduce the cross-color of adjacent sub-pixels without reducing the light-emitting area of the light-emitting layer.

In an exemplary embodiment, the first electrode includes a light reflective material. The embodiments of the present disclosure may use the reflection of the first electrode to improve the light-emitting efficiency of the light-emitting layer. For example, the first electrode includes a first conductive layer and a second conductive layer which are stacked, and a reflective layer disposed between the first conductive layer and the second conductive layer. Herein, the first conductive layer and the second conductive layer may be made of ITO (Indium Tin Oxide), and the reflective layer may be made of silver.

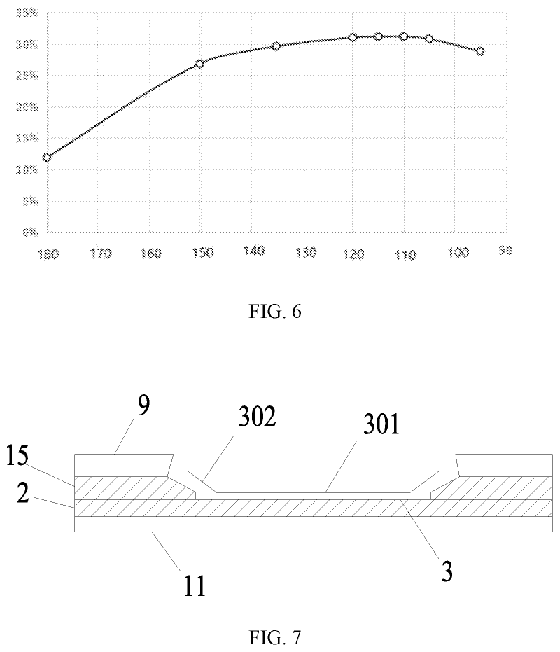

FIG. 6 is a curve graph of the first interior angle a and the light-emitting efficiency increased by the light-emitting structure layer according to an embodiment of the present disclosure. In FIG. 6, an abscissa is an angle of the first interior angle a. In FIG. 6, an ordinate shows the light-emitting efficiency increased by the light-emitting structure layer. As shown in FIG. 6, in the embodiment of the present disclosure, the first interior angle a is 105-135 degrees, and when the first interior angle a is 105-135 degrees, the light-emitting efficiency of the light-emitting structure layer can be optimized.

As shown in FIG. 4, the light-emitting structure layer 7 further includes a first planarization layer 2 disposed on the drive structure layer 11 and a second planarization layer 15 disposed on the first planarization layer 2, wherein an opening is formed in the second planarization layer 15, and a second slope angle b is formed between a sidewall of the opening and a surface of the first planarization layer 2, and the second slope angle b is greater than 0 and less than 90 degrees. The first electrode 3 is deposited and formed in the opening. A first part 301 of the first electrode 3 is disposed on a bottom wall of the opening, and a second part 302 of the first electrode 3 is disposed on a side wall of the opening. A through hole is formed in the first planarization layer 2, and the first electrode 3 is connected to the drive structure layer 11 through the through hole. The second slope angle b is used to form a second part 302 in the first electrode 3, so that a first interior angle a is formed between the first part 301 and the second part 302. Herein, the first planarization layer 2 and the second planarization layer 15 may be made of a light reflective material. The embodiment of the present disclosure may utilize the reflection of the first planarization layer 2 and the second planarization layer 15 to improve the light-emitting efficiency of the light-emitting layer.

In an exemplary embodiment, the opening in the second planarization layer 15 exposes the first planarization layer 2, and the first part 301 in the first electrode 3 is disposed on the first planarization layer 2 in the opening.

As shown in FIG. 4, the light-emitting structure layer 7 further includes a pixel definition layer 9 disposed on the second planarization layer 15, a pixel opening is formed in the pixel definition layer 9, the pixel opening exposes the first part 301 and the second parts 302 of the first electrode 3. The light-emitting layer 5 and the second electrode 12 are stacked on the pixel opening, and the light-emitting layer 5 is connected to the first electrode 3. Among them, the pixel definition layer 9 may be made of a light reflective material. For example, the pixel definition layer 9 may be made of a resin material doped with inorganic particles. For example, the pixel definition layer 9 may be made of resin system materials such as polyimide, epoxy resin, acrylic acid doped with inorganic particles such as SiO or TiO. The embodiment of the present disclosure may utilize the reflection of the pixel definition layer 9 to improve the light-emitting efficiency of the light-emitting layer.

As shown in FIG. 4, the light-emitting structure layer further includes at least one of a hole injection layer and a hole transport layer which are sequentially stacked between the first electrode and the light-emitting layer, and/or the light-emitting structure layer further includes at least one of a charge generation layer, an electron transport layer and an electron injection layer which are sequentially stacked and disposed between the light-emitting layer and the second electrode, and at least one of the hole injection layer, the hole transport layer, the charge generation layer, the electron transport layer and the electron injection layer includes a third groove portion which is recessed towards the base substrate. For example, the light-emitting structure layer includes a first electrode, a hole injection layer, a hole transport layer, a light-emitting layer, a charge generation layer, an electron transport layer, an electron injection layer and a second electrode which are sequentially stacked. Among them, the hole injection layer, the hole transport layer, the charge generation layer, the electron transport layer and the electron injection layer all include a third groove portion recessed towards the base substrate.

As shown in FIG. 4, the first electrode 3 further includes a third part 303 connected to the second part 302, wherein the third part 303 is disposed on the second planarization layer 15 and the third part 303 is located between the second planarization layer 15 and the pixel definition layer 9.

In an exemplary embodiment, an area of the third part 303 is 5%-15% of an area of the pixel opening. In the embodiment of the present disclosure, by controlling the area of the third part 303, the area of the third part 303 is avoided from too large, which results in reflected light of the third part 303 and causes cross-color between adjacent sub-pixels.

FIG. 7 is a second sectional view of a light-emitting structure layer in a display substrate according to an embodiment of the present disclosure. As shown in FIG. 7, the second part 302 is disposed on a sidewall of an opening of the second planarization layer 2, so as to prevent arrangement of a sub-electrode on a contact surface between the second planarization layer 2 and the pixel definition layer 9, and further prevent the reflected light of the sub-electrode from causing the cross-color between adjacent sub-pixels.

In an exemplary embodiment, as shown in FIG. 3, an isolation post 14 is disposed between adjacent color conversion layers 8, and the isolation post 14 is configured to prevent mutual cross-coloring between adjacent color conversion layers 8, and to improve a utilization rate of light emission of the color conversion layers 8. A vertical section of the isolation post 14 may be a straight trapezoid or an inverted trapezoid.

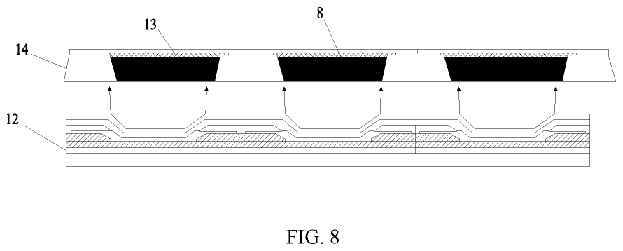

FIG. 8 is a sectional view of a display apparatus according to an embodiment of the present disclosure. As shown in FIG. 8, the display apparatus of the embodiment of the present disclosure includes the display substrate 12 of the foregoing embodiments and a counter substrate 13, wherein the counter substrate 13 and the display substrate 12 are disposed in alignment.

The display apparatus of the embodiment of the present disclosure may be any product or component with a display function, such as a mobile phone, a tablet computer, a television, a display, a laptop computer, a digital photo frame, and a navigator.

An embodiment of the present disclosure further provides a method for manufacturing a display substrate, including:

forming a light-emitting structure layer on a base substrate; the light-emitting structure layer includes a first electrode, a second electrode and a light-emitting layer disposed between the first electrode and the second electrode, wherein the first electrode at least includes a first part and a second part which are connected to each other, and a first interior angle is formed between the first part and the second part, and the first interior angle is greater than 0 and less than 180 degrees; and

forming a color conversion layer on a light exiting side of the light-emitting structure layer.

In the description of embodiments of the present disclosure, orientation or positional relations indicated by terms “middle”, “upper”, “lower”, “front”, “back”, “vertical”, “horizontal”, “top”, “bottom”, “inside”, “outside” and the like are based on the orientation or positional relations shown in the drawings, and are for the purpose of ease of description of the present disclosure and simplification of the description only, but are not intended to indicate or imply that the mentioned device or element must have a specific orientation, or be constructed and operated in a particular orientation, and therefore they should not be construed as limitation to the present disclosure.

In the description of the embodiments of the present disclosure, it should be noted that unless otherwise clearly specified and defined, the terms “install”, “couple”, “connect” should be broadly interpreted, for example, a connection may be a fixed connection, or a detachable connection, or an integrated connection; it may be a mechanical connection or an electrical connection; it may be a direct connection, or may be an indirect connection through an intermediary, or may be an internal connection between two elements. Those of ordinary skills in the art may understand meanings of the above terms in the present disclosure according to a situation.

Although the implementation modes of the present disclosure are disclosed above, the contents are only implementation modes adopted to easily understand the present disclosure and not intended to limit the present disclosure. Those skilled in the art may make any modifications and variations to implementation forms and details without departing from the spirit and scope disclosed by the present disclosure. However, the patent protection scope of the present disclosure should also be subject to the scope defined by the appended claims.

What is claimed is:

1. A display substrate, comprising: a base substrate, a light-emitting structure layer disposed on the base substrate, and a color conversion layer disposed on a light-exiting side of the light-emitting structure layer,
the light-emitting structure layer comprises a first electrode, a second electrode and a light-emitting layer disposed between the first electrode and the second electrode, wherein the first electrode at least comprises a first part and a second part which are connected to each other, and a first interior angle is formed between the first part and the second part, and the first interior angle is greater than 0 and less than 180 degrees.

2. The display substrate according to claim 1, wherein the first interior angle is greater than or equal to 90 degrees and less than 180 degrees.

3. The display substrate according to claim 2, wherein the first interior angle is greater than or equal to 110 degrees and less than 180 degrees.

4. The display substrate according to claim 1, wherein the light-emitting layer comprises a first groove portion recessed towards the base substrate, and the first groove portion is disposed on the first electrode.

5. The display substrate according to claim 4, wherein the second electrode comprises a second groove portion recessed towards the base substrate, and the second groove portion is disposed on the first groove portion.

6. The display substrate according to claim 1, wherein the light-emitting structure layer further comprises a first planarization layer disposed on the base substrate and a second planarization layer disposed on the first planarization layer, an opening is formed in the second planarization layer, and a second slope angle is formed between a side wall of the opening and the first planarization layer; the second slope angle is greater than 0 and less than or equal to 90 degrees; the first part is disposed on a bottom wall of the opening and the second part is disposed on the side wall of the opening.

7. The display substrate according to claim 6, wherein the light-emitting structure layer further comprises a pixel definition layer disposed on the second planarization layer, wherein the pixel definition layer is provided with a pixel opening, and the pixel opening exposes the first part and the second part.

8. The display substrate according to claim 7, wherein the first electrode further comprises a third part connected to the second portion, and the third part is located between the second planarization layer and the pixel definition layer.

9. The display substrate according to claim 8, wherein an area of the third part is 5%-15% of an area of the pixel opening.

10. The display substrate according to claim 7, wherein the second planarization layer and/or the pixel definition layer are made of a light reflective material.

11. The display substrate according to claim 10, wherein a material of the pixel definition layer is a resin material doped with inorganic particles.

12. The display substrate according to claim 2, wherein the first electrode comprises a light reflective material.

13. The display substrate according to claim 12, wherein the first electrode comprises a first conductive layer, a second conductive layer which are stacked, and a reflective layer disposed between the first conductive layer and the second conductive layer.

14. The display substrate according to claim 13, wherein the first interior angle is 105 degrees-135 degrees.

15. The display substrate according to claim 1, wherein the light-emitting structure layer further comprises at least one of a hole injection layer and a hole transport layer which are sequentially stacked between the first electrode and the light-emitting layer; and/or the light-emitting structure layer further comprises at least one of a charge generation layer, an electron transport layer and an electron injection layer which are sequentially stacked and disposed between the light-emitting layer and the second electrode, and at least one of the hole injection layer, the hole transport layer, the charge generation layer, the electron transport layer and the electron injection layer comprises a third groove portion which is recessed towards the base substrate.

16. A display apparatus comprising a display substrate and a counter substrate, wherein the counter substrate and the display substrate are disposed in alignment, the display substrate comprises a base substrate, a light-emitting structure layer disposed on the base substrate and a color conversion layer disposed on a light exiting side of the light-emitting structure layer, the light-emitting structure layer comprises a first electrode, a second electrode and a light-emitting layer disposed between the first electrode and the second electrode, wherein the first electrode at least comprises a first part and a second part which are connected to each other, and a first interior angle is formed between the first part and the second part, and the first interior angle is greater than 0 and less than 180 degrees.

17. The display apparatus according to claim 16, wherein the light-emitting layer comprises a first groove portion recessed towards the base substrate, and the first groove portion is disposed on the first electrode.

18. The display apparatus according to claim 16, wherein the light-emitting structure layer further comprises a first planarization layer disposed on the base substrate and a second planarization layer disposed on the first planarization layer, wherein an opening is formed in the second planarization layer, and a second slope angle is formed between a side wall of the opening and the first planarization layer; the second slope angle is greater than 0 and less than or equal to 90 degrees; the first part is disposed on a bottom wall of the opening and the second part is disposed on a side wall of the opening.

19. The display apparatus according to claim 16, wherein the light-emitting structure layer further comprises at least one of a hole injection layer and a hole transport layer which are sequentially stacked between the first electrode and the light-emitting layer; and/or the light-emitting structure layer further comprises at least one of a charge generation layer, an electron transport layer and an electron injection layer which are sequentially stacked and disposed between the light-emitting layer and the second electrode, and at least one of the hole injection layer, the hole transport layer, the charge generation layer, the electron transport layer and the electron injection layer comprises a third groove portion which is recessed towards the base substrate.

20. A method for manufacturing a display substrate, comprising:
forming a light-emitting structure layer on a base substrate; wherein the light-emitting structure layer comprises a first electrode, a second electrode and a light-emitting layer disposed between the first electrode and the second electrode, the first electrode at least comprises a first part and a second part which are connected to each other, and a first interior angle is formed between the first part and the second part, and the first interior angle is greater than 0 and less than 180 degrees; and
forming a color conversion layer on a light exiting side of the light-emitting structure layer.
